(19) United States
(12) Patent Application Publication
(10) Pub. No.: US 2008/0141511 A1
(43) Pub. Date: Jun. 19, 2008

(54) Methods of forming piezoelectric resonator having resonation structure

(76) Inventors: Ki-Hyun Kim, Yongin-si (KR); Jae-Hyung Choi, Yongin-si (KR); Ju-Ho Kim, Ansan-si (KR); Su-Min Ko, Seoul (KR)

Correspondence Address: Howard IP Law Group, P.O. Box 226, Fort Washington, PA, 19034, US

(21) Appl. No.: 11/655,436

(22) Filed: Jan. 19, 2007

(30) Foreign Application Priority Data
Dec. 14, 2006 (KR) 10-2006-0128011

(51) Int. Cl. H03H 3/02

(52) U.S. Cl. 29/25.35; 29/25.42; 310/313 B; 310/358

(57) ABSTRACT

A method of forming a piezoelectric resonator having a resonation structure is provided. According to the method, it is possible to simplify a manufacturing process of the piezoelectric resonator and raise the yield of the resonation structure from a green body in the manufacturing process. The method includes preparing a base structure, a protection structure, and a green body. The green body has polarized electrodes on selected two different surfaces, respectively. The green body has crystals having polarization axes aligned parallel to each other toward a predetermined direction. Resonant plates are formed by cutting the green body and the polarized electrodes to a predetermined width. Resonant electrodes are formed on the resonant plates. Resonation structures are formed by cutting the resonant electrodes and the resonant plates. Finally, a piezoelectric resonator is formed by interposing the resonation structure between the protection structure and the base structure.

### CROSS-REFERENCE TO RELATED APPLICATION

This patent application claims priority from Korean Patent Application No. 10-2006-0128011, filed Dec. 14, 2006, the contents of which are hereby incorporated by reference in their entirety.

### BACKGROUND OF THE INVENTION

1. Field of the Invention

The present invention relates to methods of forming a piezoelectric resonator, and more particularly, to methods of forming a piezoelectric resonator having a resonation structure.

2. Description of the Related Art

In general, piezoelectric resonators are electrical discrete devices which have a resonation structure and resonate at a specific frequency. The resonation structure has a resonant pattern, resonant connection electrodes, and resonant electrode patterns. To realize this structure, the resonation structure may be formed by grinding a green body to a target thickness, forming the resonant patterns by cutting the green body to a predetermined width, selecting one of the resonant patterns to polarize, and sequentially forming the resonant connection patterns and the resonant electrode patterns on the selected resonant pattern. The green body may be formed of a piezoelectric material.

However, the piezoelectric resonator may have the resonation structure and resonate at a specific frequency and a similar frequency. It is because the resonation of the piezoelectric resonator depends on the thickness of the resonant pattern in the resonation structure. Here, the thickness of the resonant pattern may depend on the steps of grinding the green body and cutting the green body to a predetermined width. Therefore, the resonant pattern may be difficult to be included in the resonation structure with a predetermined thickness. It is also difficult to obtain the resonation structure having the green body with a high yield. It is because the resonation structure depends on the steps of forming the resonant patterns by cutting the green body to a predetermined width, selecting one of the resonant patterns to polarize, and sequentially forming the resonant connection electrodes and the resonant electrode patterns on the selected resonant pattern.

A method of forming such a resonation structure (piezoelectric resonant device) is disclosed in Korean Patent Publication No. 1984-0003164 by Inoue Jiro. According to Korean Patent Publication No. 1984-0003164, a rectangular ceramic plate is prepared. Lapping is performed on the ceramic plate. Conductive thin films are formed on the ceramic plate. The ceramic plate is polarized using the conductive thin film. A chip is formed on the ceramic plate by using a dicing saw technique. Electrodes are disposed on the chip, and thus a piezoelectric resonant device is formed.

However, the method of forming the piezoelectric resonant device provides a piezoelectric resonant device occupying a large space. It is because the piezoelectric resonant device has electrodes and conductive thin films electrically separated from each other on the same surface of the chip. Here, the conductive thin films do not contribute to the resonation of the piezoelectric resonant device. The electrodes contribute to the resonation of the piezoelectric resonant device. Accordingly, the piezoelectric resonant device has the chip with a large volume in order to maintain the area occupied by the electrodes and the conductive thin films.

### SUMMARY OF THE INVENTION

An embodiment of the invention provides methods of forming a piezoelectric resonator, which can simplify a manufacturing process of a resonation structure, ensure the resonation structure with a high yield from a green body, and minimize the volume occupied by the resonation structure.

In one aspect, the invention is directed to methods of forming a piezoelectric resonator having a resonation structure.

In a first embodiment, a green body surrounded by six planes is prepared. Polarized electrodes are disposed on two surfaces of the green body opposite to each other, respectively. The green body is polarized. A resonant structural plate is formed by separating the two surfaces of the green body opposite to each other by a predetermined width, and cutting the green body and the polarized structural plate to the predetermined width. The resonant structural plate has polarized electrode patterns and a resonant green body disposed between the polarized electrode patterns. Resonant electrodes are formed on the resonant structural plate. The resonant electrodes are in contact with the respective polarized electrode patterns, and formed to overlap each other with the resonant green body disposed therebetween. A resonation structure is formed by separating the resonant green body by a predetermined width to pass between the polarized electrode patterns and cutting the resonant structural plate and the resonant electrodes to the predetermined width.

In a second embodiment, a green body is formed by performing a pressing technique on a green compact. The green body is formed to be surrounded by six planes. Polarized electrodes are formed on the green body. The polarized electrodes are formed to be disposed respectively on two surfaces of the green body opposite to each other using a sputtering technique. The green body is polarized. A resonant structural plate is formed by separating the two surfaces of the green body opposite to each other by a predetermined width and cutting the green body and the polarized electrodes to the predetermined width using a wire saw technique. The resonant structural plate has polarized electrode patterns and a resonant green body disposed between the polarized electrode patterns. Resonant electrodes are formed on the resonant structural plate. The resonant electrodes are in contact with the polarized electrode patterns, and overlap each other with the resonant green body disposed therebetween. A resonation structure is formed by separating the resonant green body by a predetermined width to pass between the polarized electrode patterns, and cutting the resonant structural plate and the resonant electrodes to a predetermined width.

In a third embodiment, a green body is formed on a green compact by a casting technique. The green body is formed to be surrounded by six planes. Polarized electrodes are formed on the green body. The polarized electrodes are formed to be disposed respectively on two surfaces of the green body opposite to each other using a screen printing technique. The green body is polarized. A resonant structural plate is formed by separating the two surfaces of the green body opposite to each other by a predetermined width, and cutting the green body and the polarized electrodes to the predetermined width using a wire saw technique. The resonant structural plate has polarized electrode patterns and a resonant green body disposed between the polarized electrode patterns. Resonant electrodes are formed on the resonant structural plate. The resonant electrodes are in contact with the polarized electrode patterns, respectively, and overlap each other with the resonant green body disposed therebetween. A resonation structure is formed by separating the resonant green body by a predetermined width to pass between the polarized electrode patterns, and cutting the resonant structural plate and the resonant electrodes to the predetermined width.

### BRIEF DESCRIPTION OF THE DRAWINGS

The foregoing and other objects, features and advantages of the invention will become more apparent from the following more particular description of exemplary embodiments of the invention and the accompanying drawings. The drawing is not necessarily to scale, emphasis instead being placed upon illustrating the principles of the invention.

FIGS. 1 to 9 are schematic views illustrating a method of forming a piezoelectric resonator having a resonation structure according to the present invention.

### DETAILED DESCRIPTION OF THE INVENTION

Methods of forming a piezoelectric resonator having a resonation structure of the present invention will now be described more fully hereinafter with reference to the accompanying drawings, in which exemplary embodiments of the invention are shown.

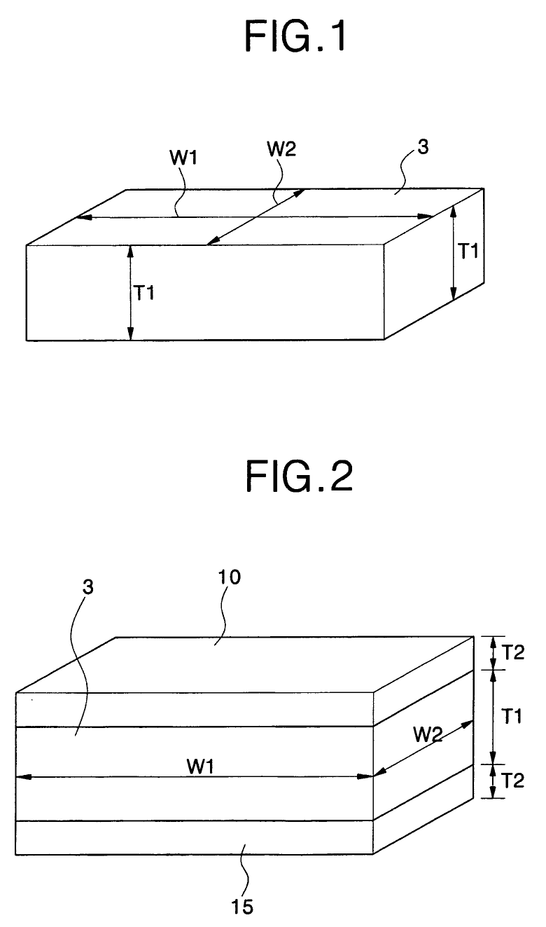

FIGS. 1 to 9 are schematic views illustrating a method of forming a piezoelectric resonator having a resonation structure according to the present invention.

Referring to FIG. 1, a green body 3 is formed from a green compact (not illustrated). The green body 3 may be formed by applying a pressing, casting or extruding technique which is well known to those skilled in the art onto the green compact. The green body 3 may be formed to be surrounded by six planes. That is, the green body 3 may be formed in a cube defined by predetermined horizontal and vertical widths W1 and W2, and a predetermined thickness T1. The green body may be formed of a piezoelectric material. Here, the green body may be formed of a plurality of crystals.

Referring to FIGS. 1 and 2, polarized electrodes 10 and 15 are formed on the green body 3. The polarized electrodes 10 and 15 may be formed to be disposed on surfaces of the green body 3 opposite to each other as illustrated in FIG. 2. The polarized electrodes 10 and 15 may be formed by a screen printing or sputtering technique, which is well known to those skilled in the art. The polarized electrodes 10 and 15 may be formed of a conductive material including silver (Ag). The screen printing or sputtering technique may be applied onto the green body 3 at least once. The respective polarized electrodes 10 and 15 may be defined by predetermined horizontal and vertical widths W1 and W2, and a predetermined thickness T2, respectively.

Meanwhile, when using the sputtering technique, the polarized electrodes 10 and 15 may be formed by depositing impurity ions on the surfaces of the green body 3 opposite to each other to the predetermined thickness T2, respectively. And, when using the screen printing technique, the polarized electrodes 10 and 15 may be formed by printing the conductive layer on the surfaces of the green body 3 opposite to each other to the predetermined thickness T2 using a mask, respectively.

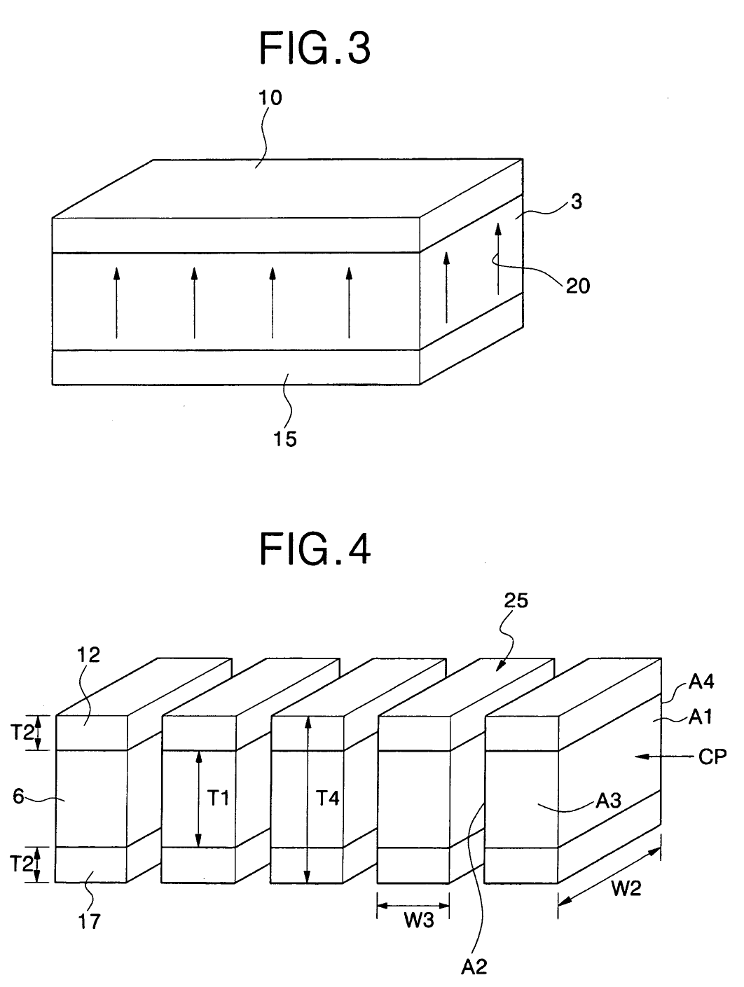

Referring to FIGS. 2 and 3, the green body 3 is polarized by directly connecting electric wires to the polarized electrodes 10 and 15. Here, the green body 3 may have crystals whose polarization axes 20 are aligned in the same direction as illustrated in FIG. 3. That is, the polarization axes 20 of the crystals in the green body 3 are disposed between the polarized electrodes 10 and 15, and thus may be aligned parallel to each other along the direction of an electric field induced between the electrodes 10 and 15.

Alternatively, an external electric field may be formed around the green body 3 so as to align the polarization axes 20 of the crystals in the green body 3 in the same direction. Here, the green body 3 may react to the external electric field, thereby generating an internal electric field between the polarized electrodes 10 and 15, and thus may align the polarization axes 20 of the crystals in the same direction as illustrated in FIG. 3. That is, the polarization axes 20 of the crystals in the green body 3 may be disposed parallel to each other along the direction of the electric field induced between the electrodes 10 and 15.

Referring to FIGS. 3 and 4, resonant structural plates 25 are formed by cutting the polarized electrodes 10 and 15 and the green body 3. Here, the resonant structural plates 25 may be formed by separating the surfaces of the green body 3 opposite to each other by a predetermined width, and cutting the green body 3 and the polarized electrodes 10 and 15 to the predetermined width as illustrated in FIG. 4. As a result, each resonant structural plate 25 may have polarized electrode patterns 12 and 17, and a resonant green body 6 disposed between the polarized electrode patterns 12 and 17.

Meanwhile, as illustrated in FIG. 4, the resonant green body 6 may have first and second surfaces A1 and A2 perpendicular to an arrow of a check point CP, and third and fourth surfaces A3 and A4 parallel to the arrow of the check point CP, when viewed from an arrow of the check point CP. Here, the resonant green body 6 may be defined by predetermined horizontal and vertical widths W2 and W3 and a predetermined thickness T1. Each polarized electrode pattern 12 or 17 may be defined by the predetermined horizontal and vertical widths W2 and W3 and a predetermined thickness T2. Accordingly, each resonant structural plate 25 may be formed in a cube defined by the predetermined horizontal and vertical widths W2 and W3 and a predetermined thickness T4.

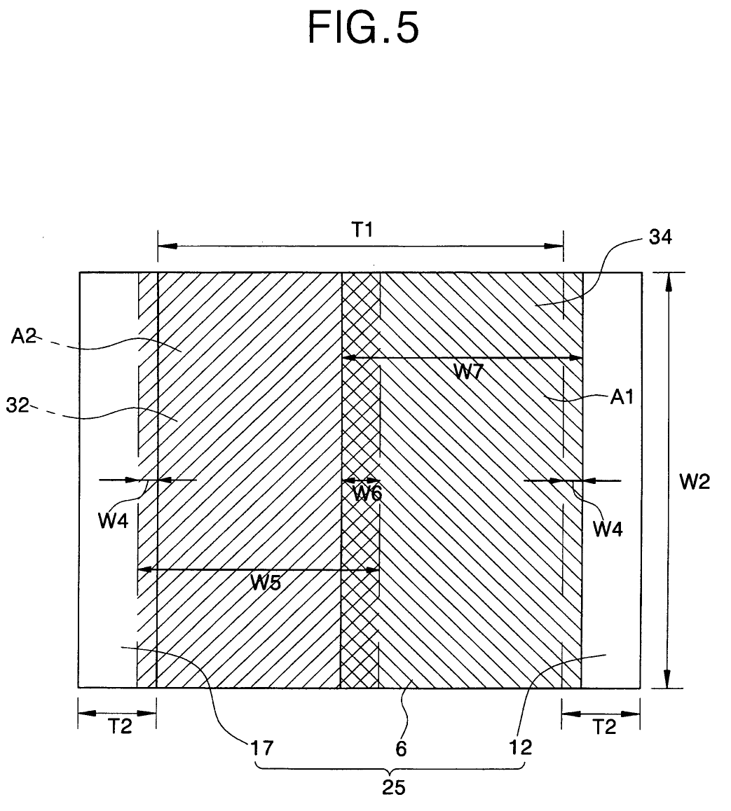

Referring to FIGS. 4 and 5, resonant electrodes 32 and 34 are formed on the resonant structural plates 25. To describe the resonant electrodes 32 and 34 in more detail, one of the resonant structural plates 25 is selected and then turned 90 degrees from FIG. 4, so that only the first and second surfaces A1 and A2 are shown, which are seen from the direction of the check point CP, as illustrated in FIG. 5. The first surface A1 of the resonant structural plate 25 is disposed upward from the space. The second surface A2 of the resonant structural plate 25 is disposed toward the space. Here, the resonant electrodes 32 and 34 may be formed on the first and second surfaces A1 and A2, respectively.

Meanwhile, the resonant electrodes 32 and 34 may overlap each other with the resonant structural plate 25 disposed therebetween. The resonant electrodes 32 and 34 may overlap each other by a predetermined width W6 through the first and second surfaces A1 and A2. The resonant electrodes 32 and 34 may be formed to be in contact with the polarized electrode patterns 17 and 12 through the first and second surfaces A1 and A2, respectively. The resonant electrodes 32 and 34 may be formed to overlap the polarized electrode patterns 17 and 12 by a predetermined width W4 through the first and second surfaces A1 and A2, respectively. And, the resonant electrodes 32 and 34 may be formed of a conductive material including Ag. The resonant electrodes 32 and 34 may be formed of at least one conductive material.

In addition, different resonant electrodes (not illustrated) may be continuously formed on the rest of the resonant structural plates 25 to have the same structures as the selected resonant structural plate 25 and the resonant electrodes 32 and 34.

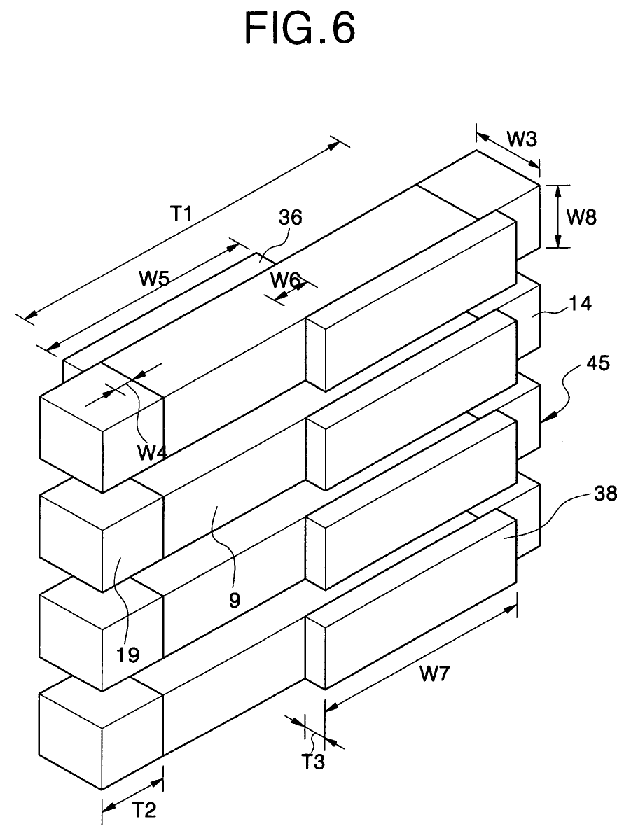

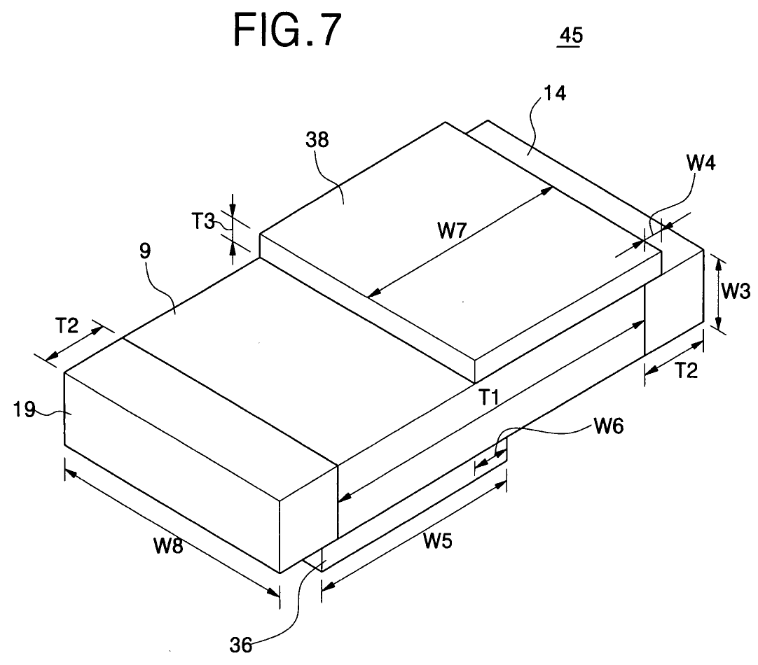

Referring to FIGS. 5 and 6, resonation structures 45 are formed by cutting the resonant electrodes 32 and 34 and the resonant structural plates 25. The resonation structures 45 may be formed by separating the first and second surfaces A1 and A2 of the resonant structural plate 25 by a predetermined width to cross the resonant electrodes 32 and 34, and cutting the resonant structural plates 25 and the resonant electrodes 32 and 34 to a predetermined width as illustrated in FIG. 6. Therefore, each resonation structure 45 has resonant electrode patterns 36 and 38, resonant connection electrodes 14 and 19, and a resonant pattern 9. The resonant pattern 9 may be formed to be surrounded by the resonant connection electrodes 14 and 19 and resonant electrode patterns 36 and 38.

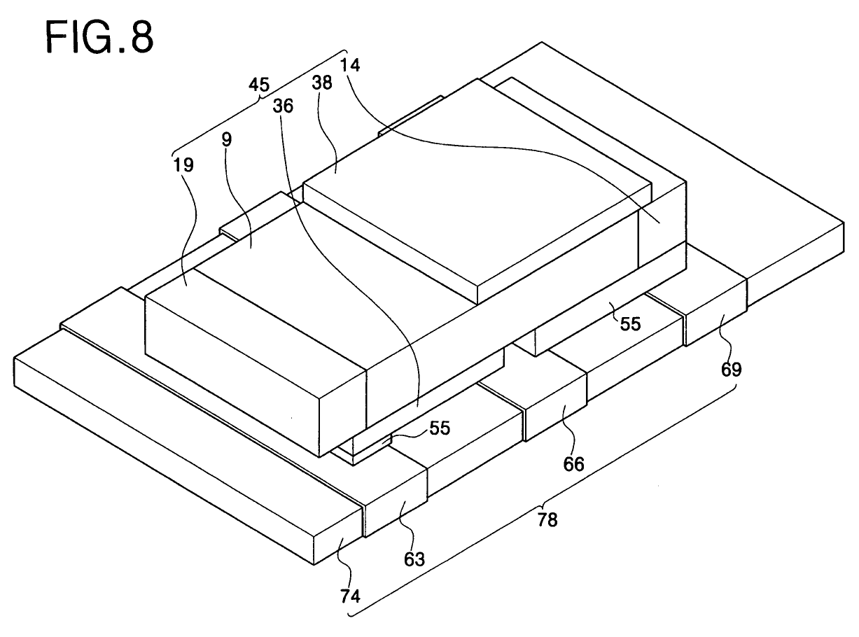

Referring to FIGS. 5 and 7, the resonation structure 45 may be formed by separating the resonant green body 6 by a predetermined width to cross the polarized electrode patterns 12 and 17, and cutting the resonant structural plate 25 and the resonant electrodes 32 and 34 to a predetermined width as illustrated in FIG. 7. Here, the resonation structure 45 has the resonant electrode patterns 36 and 38, the resonant connection electrodes 14 and 19, and the resonant pattern 9 which correspond to the resonant electrodes 32 and 34, the polarized electrode patterns 12 and 17, and the resonant green body 6, respectively. The resonant electrode patterns 36 and 38 may be formed to project from a top surface of the resonant pattern 9 and to overlap each other by a predetermined width W6 on the resonant pattern 9.

Meanwhile, one pattern 36 of the resonant electrode patterns may be formed to have predetermined horizontal and vertical widths W5 and W8 and a predetermined thickness T3. The other pattern 38 of the resonant electrode patterns may be formed to have predetermined horizontal and vertical widths W7 and W8 and the predetermined thickness T3. The resonant connection electrodes 14 and 19 may be formed on the resonant pattern 9 to overlap the resonant electrode patterns 38 and 36 by a predetermined width W4, respectively. Here, the resonant connection electrodes 14 and 19 may be defined by predetermined horizontal and vertical widths T2 and W8 and a predetermined thickness W3.

The resonation structure 45 may have the predetermined thickness T1 of the green body 3 of FIG. 1 as a predetermined length of the resonant pattern 9. Accordingly, in order to form the resonation structure 45, the green body 3 of FIG. 1 does not need to be grinded. Moreover, since the polarized electrode patterns 12 and 17 of FIG. 4 or 5 are used as the resonant connection electrodes 14 and 19, respectively, it is not necessary to separately form side electrodes related to the resonant electrode patterns 36 and 38. Also, the invention can simplify a manufacturing process, so that it is possible to obtain the resonation structure 45 having a high yield from the green body 3. As a result, in the resonation structure 45 according to the present invention, the resonant connection electrodes 14 and 19 are disposed on different surfaces from each other in the resonant pattern 9, and the resonant electrode patterns 36 and 38 are also disposed on different surfaces from each other in the resonant pattern 9, and thus it is possible to reduce its volume compared to conventional art.

Referring to FIGS. 6 and 8, one of the resonation structures 45 is selected and then formed on a base structure 78. The base structures 78 may be prepared in the same number as the resonation structures 45. The base structure 78 may have a base plate 74 and three base electrodes 63, 66 and 69 as shown in FIG. 8. The base electrodes 63, 66 and 69 may be formed to be spaced a predetermined distance apart from each other on the base plate 74.

The base electrodes 63, 66 and 69 may be formed of a conductive material including tin (Sn). The base plate 74 may be formed of an insulating material including ceramic. In each resonation structure 45, the resonant connection electrodes 14 and 19 are disposed on different surfaces of the resonant pattern 9, respectively, and the resonant electrode patterns 36 and 38 are also disposed on different surfaces of the resonant pattern 9, respectively, thereby contributing to reduce the volume of the base structure 78 compared to the conventional art.

Meanwhile, the base structure 78 may be electrically connected with one selected from the resonation structures 45 using an electrode adhesive agents 55. The electrode adhesive agents 55 serve to electrically connect the resonant electrode patterns 36 and 38 and the electrode connection electrodes 14 and 19 to two electrodes 63 and 69 selected from the base electrodes 63, 66 and 69. As a result, the resonant electrode patterns 36 and 38 and the resonant connection electrodes 14 and 19 are electrically connected to the two base electrodes 63 and 69, and thus the resonant pattern 9 may resonate.

Also, different base structures (not illustrated) may be continuously formed on the rest of the resonation structures 45, respectively, to have the same structures as the selected resonation structure 45 and the base structure 78.

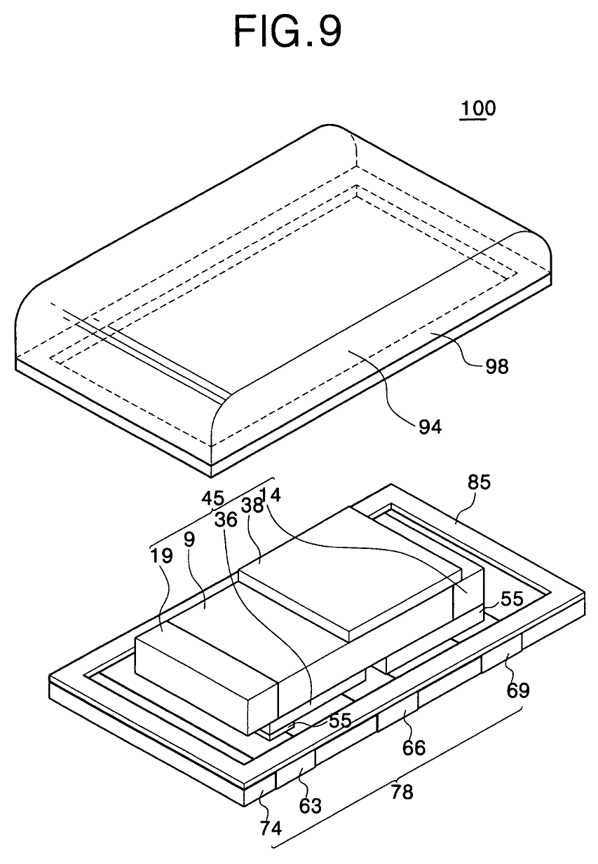

Referring to FIGS. 8 and 9, a protection adhesive agent 85 is formed on the base structure 78. The protection adhesive agent 85 may be formed on the base structure 78 as illustrated in FIG. 9 to surround one selected from the resonation structures 45. The protection adhesive agent 85 may be an insulating adhesive agent including silicon (Si). A protection structure 94 may be formed on the base structure 78 to cover one selected from the resonation structures 45. The protection structure 94 may be formed of a conductive material including Fe—Ni and Al₂O₃.

Meanwhile, the protection structure 94 may be bonded to one selected from the resonation structures 45 using a contact surface 98 between the protection adhesive agent 85 and the protection structure 94. As a result, the selected resonation structure 45, the protection structure 94, and the base structure 78 may constitute a piezoelectric resonator 100 according to the present invention. Subsequently, other piezoelectric resonators may be continuously formed by disposing other base structures and protection structures (not illustrated) on the rest of the resonation structures 45 to have the same structures as the selected resonation structure 45, the base structure 78, and the protection structure 94.

As described above, methods of forming a piezoelectric resonator having a resonation structure are provided. Accordingly, a resonation structure can be produced by a simple process, obtained with a high yield from a green body, and occupy less space.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a piezoelectric resonator, comprising:
preparing a green body surrounded by six planes;
forming polarized electrodes on the green body, the polarized electrodes being disposed on two surfaces of the green body opposite to each other, respectively;
polarizing the green body;
forming a resonant structural plate by separating the two surfaces of the green body opposite to each other by a predetermined width, and cutting the green body and the polarized electrodes to the predetermined width to form a resonant structural plate, the resonant structural plate having polarized electrode patterns and a resonant green body disposed between the polarized electrode patterns;
forming resonant electrodes on the resonant structural plate, the resonant electrodes being in contact with the respective polarized electrode patterns and formed to overlap each other with the resonant green body disposed therebetween; and
forming a resonation structure by separating the resonant green body by a predetermined width to pass between the polarized electrode patterns and cutting the resonant structural plate and the resonant electrodes to the predetermined width.

2. The method according to claim 1, wherein forming the resonation structure and the resonant structural plate is performed by using a wire saw technique.

3. The method according to claim 1, wherein the resonation structure is formed to have resonant electrode patterns, resonant connection electrodes, and a resonant pattern which correspond to the resonant electrodes, the polarized electrode patterns and the resonant green body, respectively.

4. The method according to claim 1, wherein the resonant electrodes are formed of at least one conductive material.

5. The method according to claim 1, wherein the green body is formed of a piezoelectric material having a plurality of crystals.

6. The method according to claim 5, wherein polarizing the green body comprises directly contacting electrical wires to the respective polarized electrodes to align polarization axes of the crystals in the green body in the same direction.

7. The method according to claim 5, wherein polarizing the green body comprises forming an electric field around the green body to align polarization axes of the crystals in the green body in the same direction.

8. The method according to claim 1, wherein forming the polarized electrodes comprises applying a sputtering technique onto the two surfaces of the green body opposite to each other at least once in order to deposit impurity ions to a predetermined thickness.

9. The method according to claim 1, wherein forming the polarized electrodes comprises forming at least one conductive layer on each of the two surfaces of the green body opposite to each other using a screen printing technique.

10. The method according to claim 5, wherein preparing the green body is performed by applying a pressing, casting or extruding technique onto a green compact.

11. A method of forming a piezoelectric resonator, comprising:
forming a green body by performing a pressing technique on a green compact, the green body being formed to be surrounded by six planes;
forming polarized electrode on the green body, the polarized electrodes being formed to be disposed respectively on two surfaces of the green body opposite to each other using a sputtering technique;
polarizing the green body;
forming a resonant structural plate by separating the two surfaces of the green body opposite to each other by a predetermined width and cutting the green body and the polarized electrodes to the predetermined width using a wire saw technique, the resonant structural plate having polarized electrode patterns and a resonant green body disposed between the polarized electrode patterns;
forming resonant electrodes on the resonant structural plate, the resonant electrodes being in contact with the polarized electrode patterns and overlapping each other with the resonant green body disposed therebetween; and
forming a resonation structure by separating the resonant green body by a predetermined width to pass between the polarized electrode patterns and cutting the resonant structural plate and the resonant electrodes to a predetermined width.

12. The method according to claim 11, wherein the resonation structure is formed to have resonant electrode patterns, resonant connection electrodes, and a resonant pattern which correspond to the resonant electrodes, the polarized electrode patterns, and the resonant green body, respectively.

13. The method according to claim 11, wherein the resonant electrodes are formed of at least one conductive material.

14. The method according to claim 11, wherein the green body is formed of a piezoelectric material having a plurality of crystals.

15. The method according to claim 14, wherein polarizing the green body comprises directly contacting electrical wires to the respective polarized electrodes to align polarization axes of the crystals in the green body in the same direction.

16. The method according to claim 14, wherein polarizing the green body comprises forming an electric field around the green body to align polarization axes of the crystals in the green body in the same direction.

17. A method of forming a piezoelectric resonator, comprising:
forming a green body by performing a casting technique on a green compact, the green body being formed to be surrounded by six planes;
forming polarized electrodes on the green body, the polarized electrodes being formed to be disposed respectively on two surfaces of the green body opposite to each other using a screen printing technique;
polarizing the green body;
forming a resonant structural plate by separating the two surfaces of the green body opposite to each other by a predetermined width and cutting the green body and the polarized electrodes to the predetermined width using a wire saw technique, the resonant structural plate having polarized electrode patterns and a resonant green body disposed between the polarized electrode patterns;
forming resonant electrodes on the resonant structural plate, the resonant electrodes being in respective contact with the polarized electrode patterns and overlapping each other with the resonant green body disposed therebetween; and
forming a resonation structure by separating the resonant green body by a predetermined width to pass between the polarized electrode patterns and cutting the resonant structural plate and the resonant electrodes to the predetermined width.

18. The method according to claim 17, wherein the resonation structure is formed to have resonant electrode patterns, resonant connection electrodes, and a resonant pattern which correspond to the resonant electrodes, the polarized electrode patterns, and the resonant green body, respectively.

19. The method according to claim 17, wherein the resonant electrodes are formed of at least one conductive material.

20. The method according to claim 17, wherein the green body is formed of a piezoelectric material having a plurality of crystals.

21. The method according to claim 20, wherein polarizing the green body comprises directly contacting electrical wires to the polarized electrodes to align polarization axes of the crystals in the green body in the same direction.

22. The method according to claim 20, wherein polarizing the green body comprises forming an electric field around the green body to align polarization axes of the crystals in the green body in the same direction.
